(19) United States
(12) Patent Application Publication
(10) Pub. No.: US 2025/0218850 A1
(43) Pub. Date: Jul. 3, 2025

(54) SEMICONDUCTOR DEVICE ARRANGEMENT

(71) Applicant: EPISTAR CORPORATION, Hsinchu (TW)

(72) Inventor: Chang-Tai HSIAO, Hsinchu (TW)

(21) Appl. No.: 18/977,641

(22) Filed: Dec. 11, 2024

(30) Foreign Application Priority Data
Dec. 29, 2023 (TW) 112151564

(51) Int. Cl. H01L 21/683; H01L 25/075; H10H 29/24

(52) U.S. Cl. CPC H01L 21/6835; H01L 25/0753; H10H 29/24; H01L 2221/68354; H01L 2221/68368; H01L 2221/68381

(57) ABSTRACT

A semiconductor device arrangement includes a carrier, an adhesive layer, several first semiconductor devices, and several second semiconductor devices. The carrier has an upper surface, and the adhesive layer is arranged on the upper surface. The several first semiconductor devices are arranged in a first region on the adhesive layer, the several second semiconductor devices are arranged in a second region on the adhesive layer, and the first region abuts the second region. Wherein, any two adjacent first semiconductor devices of the several first semiconductor devices are separated by a first distance, any one of the several first semiconductor devices and any one of the several second semiconductor devices, which are adjacent to each other, are separated by a second distance, and the first distance is larger than the second distance.

### CROSS-REFERENCE TO RELATED APPLICATIONS

This application claims priority to, and the benefit of, Taiwan Patent Application Number 112151564 filed on Dec. 29, 2023, the entire content of which is hereby incorporated by reference herein in its entirety.

### TECHNICAL FIELD

The present disclosure relates to a semiconductor device arrangement, and in particular to a semiconductor device arrangement in which a plurality of semiconductor devices is arranged on a substrate or a carrier, and the method of manufacturing the same.

### DESCRIPTION OF BACKGROUND ART

The light-emitting diode (LED) is a semiconductor device which has many advantages, such as low power consumption, low heat generation, long operating life, high impact resistance, small size, fast reaction speed, and good photoelectric properties. Therefore, it is widely used in electronic equipment such as household appliances, equipment indicators, and display devices.

The LED continues to develop toward miniaturization, such as reducing the width to smaller than 100 μm, 50 μm, or 30 μm. In order to apply miniaturized LEDs to displays, a large number of LEDs are transferred between different substrates, which is called mass transfer. How to carry out efficient mass transfer and ensure high precision, high throughput and low cost of mass transfer results is a goal that the industry strives to pursue.

A high-speed transfer method is to divide a LED arrangement into a plurality of LED regions, and each LED region includes a plurality of LEDs. One LED region is used as a smallest transfer unit for transferring, and all LEDs in one or multiple LED regions are transferred simultaneously.

### SUMMARY OF THE APPLICATION

The present disclosure provides a semiconductor device arrangement including a carrier, an adhesive layer, a plurality of first semiconductor devices, and a plurality of second semiconductor devices. The carrier has an upper surface. The adhesive layer is arranged on the upper surface. The plurality of first semiconductor devices is arranged in a first region on the adhesive layer, and the plurality of second semiconductor devices is arranged in a second region on the adhesive layer, wherein the first region abuts the second region. Any two adjacent first semiconductor devices of the plurality of first semiconductor devices are separated by a first distance, any one first semiconductor device of the plurality of first semiconductor devices and any one second semiconductor device of the plurality of second semiconductor devices, which are adjacent to each other, are separated by a second distance, and the first distance is larger than the second distance.

### BRIEF DESCRIPTION OF THE DRAWINGS

The embodiments of the present disclosure may be more fully understood by reading the subsequent detailed description and examples with references made to the accompanying drawings. In addition, for clarity, the features in the drawings may not be drawn to actual scale, so some features in some drawings may be deliberately enlarged or reduced in size, wherein:

FIG. 1A shows a top view of a LED wafer in accordance with one embodiment of the present disclosure.

FIG. 1B shows a cross-sectional view along A-A′ in FIG. 1A.

FIG. 2A shows a top view of a LED carrier in accordance with one embodiment of the present disclosure.

FIG. 2B shows a cross-sectional view along B-B′ in FIG. 2A.

FIG. 3A shows a schematic diagram of a regional laser transferring process on the LED wafer 100 in accordance with one embodiment of the present disclosure.

FIG. 3B shows a simulation diagram of the regional laser transferring process in a region R in FIG. 3A.

FIG. 3C shows a top view of a portion of a LED carrier in accordance with one embodiment of the present disclosure.

FIG. 3D shows a schematic diagram of a gas flow along C-C′ in FIG. 3C.

FIG. 4A shows a top view of a LED wafer in accordance with one embodiment of the present disclosure.

FIG. 4B shows a top view of a LED carrier in accordance with one embodiment of the present disclosure.

FIGS. 5A-5C illustrate a regional transferring process in accordance with one embodiment of the present disclosure.

### DETAILED DESCRIPTION OF THE APPLICATION

The embodiments of the present disclosure will be described in detail below with reference to the accompanying drawings, so that those skilled in the art to which the present disclosure belongs can fully understand the spirit of the present disclosure. The present disclosure is not limited to the following embodiments, but may be implemented in other forms. In this specification, there are some same reference numerals, indicating components with the same or similar structure, function and principle. For simplicity of description, components with the same reference numerals will not be described again.

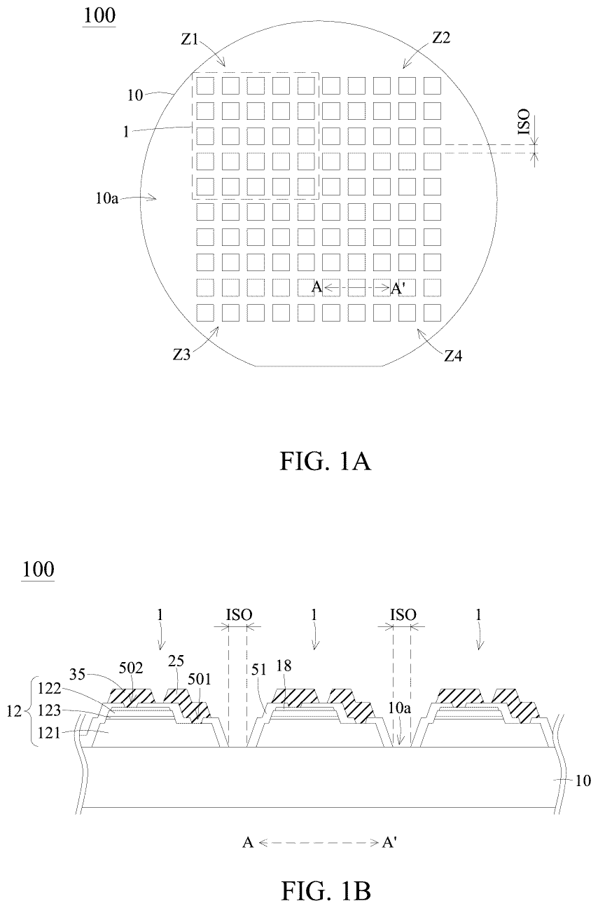

FIG. 1A shows a top view of a semiconductor wafer, and FIG. 1B shows a cross-sectional view along A-A′ in FIG. 1A. Referring to FIG. 1B, in one embodiment, a semiconductor device is a LED 1. The LED wafer 100 includes a plurality of LEDs 1 formed on a substrate 10. A plurality of semiconductor stacks 12 is formed on an upper surface 10a of the substrate 10, wherein each semiconductor stack 12 includes a first semiconductor layer 121, an active region 123, and a second semiconductor layer 122. A transparent conductive layer 18, an insulating layer 51, a first electrode 25, and a second electrode 35 can be selectively formed on each semiconductor stack 12 to form the LED 1. Two adjacent LEDs 1 are formed on the substrate 10 and separated from each other by a distance ISO. In one embodiment, the plurality of LEDs 1 is arranged on the substrate 10 in a two-dimensional array.

The LED wafer 100 includes a plurality of LED regions in virtual, such as LED regions Z1-Z4. Each LED region includes N LEDs 1 arranged in an array. In one embodiment, there are 25 (5×5) LEDs 1 arranged in an array in one LED region. The arrangement of the LEDs 1, the allocations of the regions, the area of each region and the quantity of the regions can be adjusted as needed.

### Substrate 10

The substrate 10 can be a growth substrate, including a GaP substrate or a GaAs substrate for growing AlGaInP thereon, or a sapphire (Al₂O₃) substrate, a GaN substrate, a SiC substrate, or an AIN substrate for growing InGaN or AlGaN thereon. The substrate 10 has an upper surface 10a. In one embodiment, the upper surface 10a is a flat surface. In another embodiment, the substrate 10 is a patterned substrate; that is, the substrate 10 has a patterned structure (not shown) on the upper surface 10a. The patterned structure includes a plurality of protrusions or a plurality of recesses. In one embodiment, light generated from the semiconductor stack 12 can be refracted by the patterned structure of the substrate 10 to increase the brightness of the light output from the LED. In addition, the patterned structure can reduce or suppress dislocations caused by lattice mismatch between the substrate 10 and the semiconductor stack 12, thereby improving the epitaxy quality of the semiconductor stack 12.

### Semiconductor Stack 12

In one embodiment, the semiconductor stack 12 is formed on the substrate 10 by metalorganic chemical vapor deposition (MOCVD), molecular-beam epitaxy (MBE), hydride vapor phase epitaxy (HVPE) or ion plating such as sputtering or evaporating.

The semiconductor stack 12 including a buffer layer (not shown), a first semiconductor layer 121, an active region 123, and a second semiconductor layer 122 are sequentially formed on the substrate 10. The buffer layer reduces the lattice mismatch and suppresses dislocation so as to improve the epitaxy quality. The material of the buffer layer includes GaN, AlGaN, or AlN. In one embodiment, the buffer layer includes a plurality of sub-layers (not shown), and the plurality of sub-layers have the same material or different materials. In one embodiment, the buffer layer includes a first sub-layer and a second sub-layer. The first sub-layer is formed by sputtering or MOCVD, and the second sub-layer is formed by MOCVD. In another embodiment, the buffer layer further includes a third sub-layer. The third sub-layer is formed by MOCVD, and the growth temperature of the second sub-layer is higher or lower than the growth temperature of the third sub-layer. In one embodiment, the first, second, and third sub-layers include the same material, such as AlN. In one embodiment, the first semiconductor layer 121 and the second semiconductor layer 122 have different conductivity types, different electrical properties, different polarities or different dopants for providing electrons or holes. For example, the first semiconductor layer 121 is an n-type semiconductor and the second semiconductor layer 122 is a p-type semiconductor. The active region 123 is formed between the first semiconductor layer 121 and the second semiconductor layer 122. Driven by a current, electrons and holes are combined in the active region 123 to convert electrical energy into optical energy for illumination. The wavelength of the light generated by the semiconductor stack 12 can be adjusted by changing the physical properties and chemical composition of one or more layers in the semiconductor stack 12.

The material of the semiconductor stack 12 includes III-V semiconductor with AlₓIn_{y}Ga(1-x-y) N or AlₓIn_{y}Ga_{(1-x-y)}P, where 0≤x, y≤1; x+y≤1. When the material of the active region 123 of the semiconductor stack 12 includes AlInGaP, the semiconductor stack 12 emits red light having a wavelength between 610 nm and 650 nm or yellow light having a wavelength between 550 nm and 570 nm. When the material of the active region of the semiconductor stack 12 includes InGaN, the semiconductor stack 12 emits blue light having a wavelength between 400 nm and 490 nm or green light having a wavelength between 490 nm and 550 nm. When the material of the active region of the semiconductor stack 12 includes AlGaN, the semiconductor stack 12 emits UV light having a wavelength between 250 nm and 400 nm. The active region 123 can be a single hetero-structure (SH), a double hetero-structure (DH), a double-side double hetero-structure (DDH), or a multi-quantum well (MQW). The material of the active region 123 can be i-type, p-type or n-type semiconductor.

### Transparent Conductive Layer 18

The transparent conductive layer 18 covers the upper surface of the second semiconductor layer 122 of the LED 1 and electrically connects with the second semiconductor layer 122. The transparent conductive layer 18 includes metal or transparent conductive material. The metal material can form a light-transmitting thin film metal layer. The transparent conductive material is transparent to the light emitted by the active region 123 and includes graphene, indium tin oxide (ITO), aluminum zinc oxide (AZO), gallium zinc oxide (GZO), zinc oxide (ZnO), or indium zinc oxide (IZO). In another embodiment, the LED 1 does not include the transparent conductive layer 18, and a portion of the second semiconductor layer 122 is exposed and connected to the second electrode 35 through an opening 502.

### Insulating Layer 51

The insulating layer 51 is transparent to the light emitted from the semiconductor stack 12, and can be a layer composed of a single insulating material or a stack composed of multiple layers of different insulating materials. In one embodiment, the insulating layer 51 is formed by alternately stacking a pair or a plurality of pairs of insulating materials with different refractive indices. The insulating material includes silicon oxide, silicon nitride, silicon oxynitride, niobium oxide, hafnium oxide, titanium oxide, magnesium fluoride, aluminum oxide, etc. In one embodiment, by selecting insulating materials with different refractive indices and the thickness thereof, the insulating layer 51 functions as a reflective structure such as distributed Bragg reflector (DBR). The reflective structure selectively reflects the light within a specific wavelength range. The insulating layer 51 can be formed by atomic layer deposition (ALD), sputtering, evaporation, spin-coating, etc. In another embodiment, the insulating layer 51 includes a stack of multiple layers of the same insulating material formed by different methods or different insulating materials formed by different methods. In one embodiment, the first semiconductor layer 121 and the transparent conductive layer 18 are exposed by openings 501, 502 of the insulating layer 51.

### Electrode

The electrodes include a first electrode 25 and a second electrode 35. The material of the electrode includes metals, such as Cr, Ti, Au, Al, Cu, Sn, Ni, Rh, W, Pt, an alloy or a laminated stack composed by the above materials.

In one embodiment, the LED 1 has a diagonal length less than 150 μm in a top view (not shown), and a distance between the first electrode 25 and the second electrode 35 is less than 30 μm. In another embodiment, the LED 1 has a diagonal length less than 100 μm in a top view (not shown), and a distance between the first electrode 25 and the second electrode 35 is less than or equal to 25 μm.

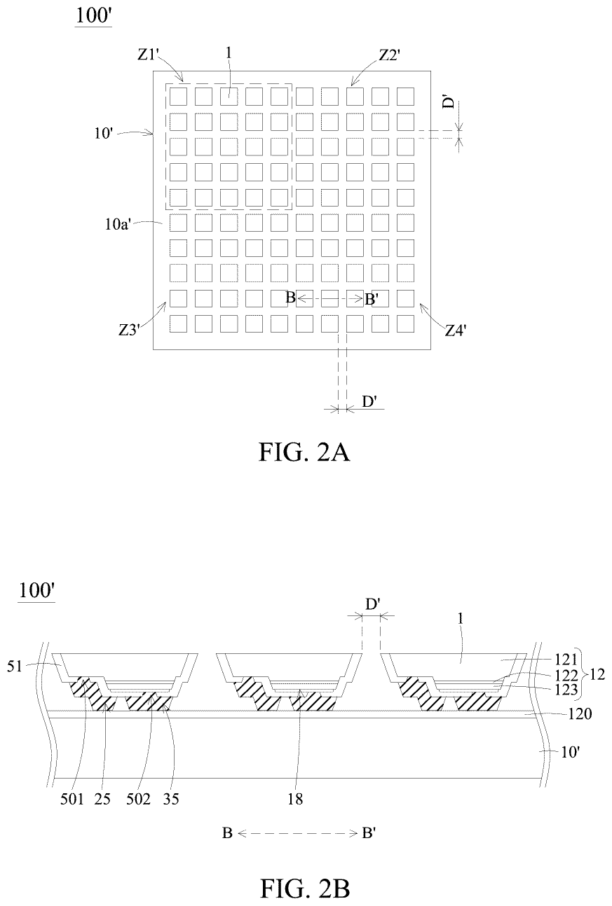

FIG. 2A shows a top view of a semiconductor device carrier in accordance with one embodiment of the present disclosure, and FIG. 2B shows a cross-sectional view along B-B′ in FIG. 2A. Referring to FIG. 2B, in one embodiment, a semiconductor device is a LED 1. The LED carrier 100′ includes a plurality of LEDs 1 formed on a carrier 10′. The plurality of LED 1 is arranged on an upper surface 10a′ of the carrier 10′ and are separated from each other by a constant distance D′. The manufacturing method, structure and material composition of the LED 1 can be referred to the relevant paragraphs mentioned above.

In one embodiment, the LED 1 is flip mounting on the carrier 10′. In order to increase the stability of the arrangement of the LEDs 1 on the carrier 10′, an adhesive layer 120 is selectively provided between the upper surface 10a′ of the carrier 10′ and the LEDs 1. In one embodiment, the LED 1 does not have a growth substrate. In one embodiment, the plurality of LEDs 1 is arranged in an array on the carrier 10′. In one embodiment, the plurality of LEDs 1 is arranged on the carrier 10′ with the first electrode 25 and the second electrode 35 facing away from the carrier 10′.

As shown in FIG. 2A, the LED carrier 100′ includes a plurality of LED regions in virtual, such as LED regions Z1′-Z4′. N LEDs 1 are arranged in an array in each LED region. In one embodiment, there are 25 (5×5) LEDs 1 arranged in an array in a LED region. The arrangement of the LEDs 1, the allocations of the regions, the area of each region and the quantity of the regions can be adjusted as needed.

### Carrier 10′

The carrier 10′ can be a non-epitaxial material or a non-growth substrate, including a ceramic substrate, a metal substrate, a glass substrate, a quartz substrate, a thermal release tape, a UV release tape, a chemical release tape, a heat-resistant tape, a blue tape, or a tape with a dynamic release layer (DRL). In one embodiment, the carrier 10′ can be penetrated by a laser beam, so that the LED 1 can be separated from the carrier 10′ through a laser lift-off (LLO) process.

### Adhesive Layer 120

The adhesive layer 120 is a continuous layer. The material of the adhesive layer 120 includes polymer, such as a resin material which can be decomposed upon an irradiation of laser beam through a laser ablation (LA) process. In one embodiment, the resin material has a laser absorption ratio between 60% and 100%, or between 80% and 100%. The adhesive layer 120 includes polyimide (PI), acrylic resin, polyepoxide (EPO), polybenzoxazole (PBO), polysiloxane, cyclic olefin polymer (COP), or benzocyclobutane (BCB), etc.

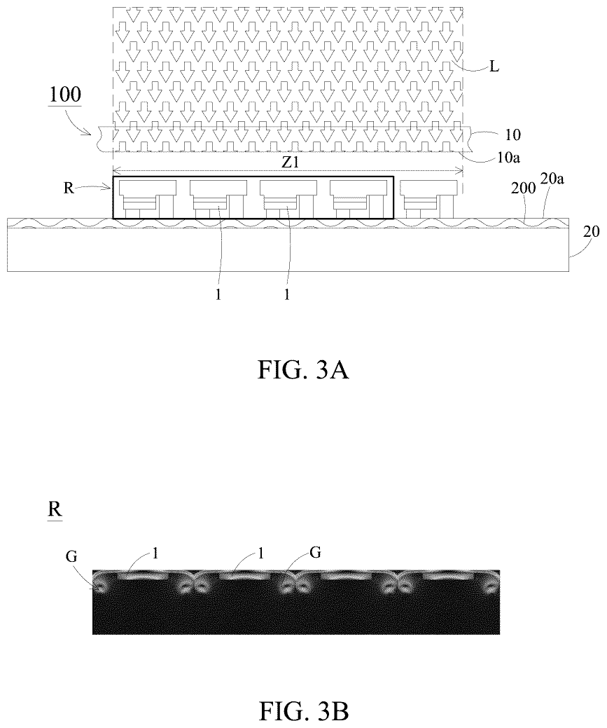

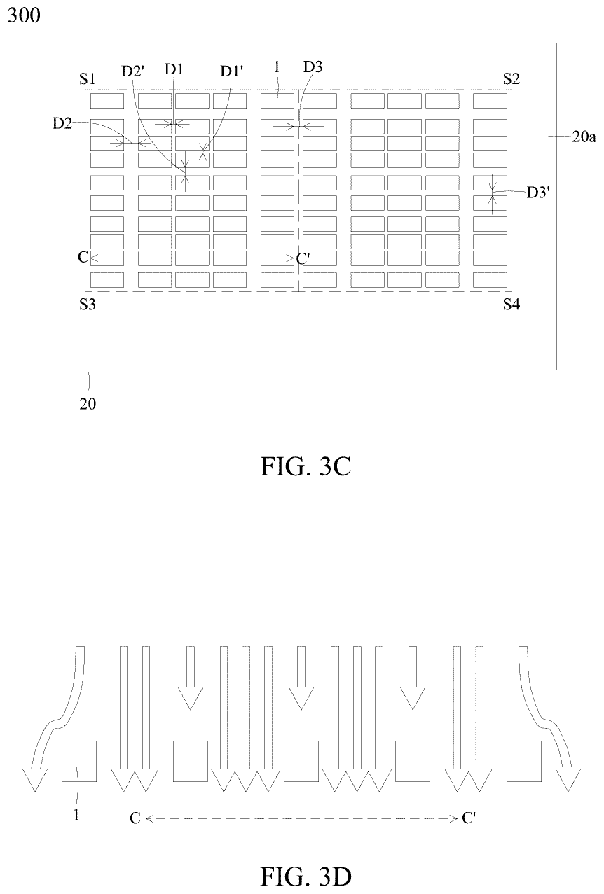

As shown in FIG. 3A, in the LED region Z1, a plurality of LEDs 1 is simultaneously irradiated with the laser beam L to separate from the substrate 10, and is bonded to a temporary carrier 20 through an adhesive layer 200. In one embodiment, there are 25 (5×5) LEDs 1 arranged in an array in a LED region. The arrangement of the LEDs 1, the allocations of the regions, the area of each region and the quantity of the regions can be adjusted as needed. The LED 1 in FIG. 3A is presented with a simplified structure (detailed are omitted), and the structure and material composition of the adhesive layer 200 and the temporary carrier 20 can be referred to the relevant paragraphs mentioned above.

FIG. 3B shows a numerical simulation diagram in a region R in FIG. 3A. As shown in FIG. 3B, a portion of the semiconductor stack 12 adjacent to the substrate 10 is decomposed to generate gas when the LED 1 is irradiated by the laser beam L. In one embodiment, the portion of the semiconductor stack 12 adjacent to the substrate 10 is III-V semiconductor with AlₓIn_{y}Ga_{(1-x-y)}N, where 0≤x, y≤1; x+y≤1. The semiconductor stack 12 is decomposed to generate N₂ gas when irradiated by the laser beam. The generated gas can push the LED 1 downward. In addition, turbulent gas flow G escaping toward both sides of the LED 1 is also generated at a side of the semiconductor stack 12 irradiated by the laser beam. According to the simulation, if the left turbulent gas flow G and the right turbulent gas flow G generated on both sides of the LED 1 have the same intensity, a horizontal resultant force of the turbulent gas flow G on both sides of the LED 1 is approximately zero. Therefore, after the LED 1 is separate from the substrate 10, the LED 1 can move straight toward the temporary carrier 20. The dropped LED is adhered to the temporary carrier 20 through the adhesive layer 200. In one embodiment, the object irradiated by the laser beam is the LED carrier 100′ as shown in FIGS. 2A and 2B. In one embodiment, depending on the composition, the adhesive layer 120 does not generate gas when irradiated by the laser beam L, but can generate shock waves due to heat conduction of the chemical reaction. Similar, according to the simulation, if the left turbulent gas flow G and the right turbulent gas flow G generated on both sides of the LED 1 have the same intensity by the shock waves, a horizontal resultant force of the turbulent gas flow G on both sides of the LED 1 is approximately zero. The LED 1 is separated from the carrier 10′ and moved straight downward toward the temporary carrier 20.

### Laser Beam L

In the regional transferring process, a light source for generating the laser beam L is selected from an argon fluoride (ArF) excimer laser that can emit laser with a wavelength of 193 nm, a krypton fluoride (KrF) excimer laser that can emit laser with a wavelength of 248 nm, or a diode-pumped solid-state (DPSS) laser that can emit laser with a wavelength of 266 nm or a wavelength of 355 nm. In one embodiment, the laser beam L which has a predetermined cross section size as shown in FIG. 3A can be formed by a beam shaping optical system, an adjustable aperture, an optical mask, etc, coupled to the light source.

FIG. 3C shows a top view of a portion of the LED carrier 300. The LED carrier 300 includes a plurality of LEDs 1 transferred from the LED wafer 100 through a reginal transferring process as shown in FIG. 3A, and arranged on the temporary carrier 20. In one embodiment, FIG. 3D is a schematic diagram of the gas flow around the LEDs 1 during the regional laser transferring process in FIG. 3A.

Referring to FIGS. 3A and 3C, the LED carrier 300 includes a temporary carrier 20, the LEDs 1 being transferred are arranged on the temporary carrier 20 in an array. The temporary carrier 20 has an upper surface 20a, and an adhesive layer 200 is arranged on the upper surface 20a. A plurality of LED regions S1-S4 in virtual is provided on the adhesive layer 200, and the LEDs 1 in the plurality of LED regions S1-S4 are respectively transferred from the LED regions Z1-Z4 of the LED wafer 100. N LEDs 1 are arranged in an array, such as 5×5 array, are located in each LED region. In one embodiment, as shown in FIG. 3A, the LEDs 1 on the LED wafer 100 are transferred to the temporary carrier 20 with the upper surface 10a facing downward. In one embodiment, five LEDs 1 in the LED region Z1 in FIG. 3A are transferred by a laser beam, and transferred on the temporary carrier 20 as shown along C-C′ in FIG. 3C. In other word, the LEDs 1 in the LED regions Z1, Z2, Z3, Z4 are transferred to the LED regions S3, S4, S1, S2 respectively.

As shown in FIG. 3C, in the LED carrier 300, the LEDs 1 arranged in an array are located in the LED regions S1-S4 respectively. In one embodiment, the LEDs 1 arranged in the LED regions have the same arrangement. The plurality of LEDs 1 in one LED region has spacings increasing outward from a central area of the LED region. In one embodiment, a horizontal distance between two adjacent LEDs 1 located in the central area of the LED region is D1, and a vertical distance between two adjacent LEDs 1 located in the central area of the LED region is D1′. A horizontal distance between two adjacent LEDs 1 located on the edge of the LED region is D2, and a vertical distance between two adjacent LEDs 1 located on the edge of the LED region is D2′. D2>D1, and D2′>D1′.

As shown in FIG. 3D. In one embodiment, the semiconductor stack 12 adjacent to the substrate 10 can be decomposed to generate gas, such as N₂ gas, and form a gas flow at the joint with the substrate 10 when the LED 1 is irradiated by the laser beam L. Since the LEDs 1 are transferred region by region, the intensity of the gas flow in the edge area and the central area are not the same. In one embodiment, the gas flow not only moves downward from the gap between the LEDs 1, but also escapes toward the edge area. As shown in FIGS.3C and 3D, no gas is generated in the area out of the LED region S1 that is not irradiated by the laser beam L. When the LED region S1 is irradiated by the laser beam L, the generated gas flow passes downward through the gaps between the plurality of LEDs 1 and also escapes laterally toward the edge of the LED region S1. As shown in FIG. 3D, the gap between two adjacent LEDs 1 located in the center of the region has more downdraft gas flow than the gap between two adjacent LEDs 1 located in the edge of the region. The pressure difference generated by gas flows with different flow rates produces a non-zero resultant force in the horizontal direction, producing an outward horizontal gas flow. The unbalanced pressure causes the LEDs 1 to move laterally when the LEDs move downward to the temporary carrier 20, so that the spacings in the plurality of LEDs 1 have been changed. That is to say, the distance between two adjacent LEDs 1 on the substrate 10 is different from the distance between two adjacent LEDs 1 on the temporary carrier 20. As shown in FIG. 3C, in one embodiment, the distance between two adjacent LEDs 1 gradually increases from the center toward the outside. Compared with the spacing on the substrate 10, in the region irradiated by the laser beam, the distance between two adjacent LEDs on the central area is smaller than the distance between two adjacent LEDs on the edge area. The maximum horizontal distance and the maximum vertical distance are respectively located between the outermost two rows and two columns of LEDs 1. The arrangement of the LEDs 1 on the temporary carrier 20 can be affected by other factors and differ from the arrangement of the LEDs 1 shown in FIG. 3C. Influencing factors include but are not limited to laser intensity, the shape and weight of the LEDs 1, and the arrangement/spacing of the LEDs 1 on the substrate 10.

As shown in FIG. 3C, in each of the LED regions S1-S4, the plurality of LEDs 1 located in one LED region has spacings increasing outward from a center of the LED region. The arrangement of the LEDs (spacing gradually increases outwards) is the same in different regions. As shown in FIG. 3C, the horizontal distances D1 and D2 and the vertical distances D1′ and D2′ between two adjacent LEDs 1 are larger than the distance ISO of the LEDs 1 located in the LED wafer 100. Located at a junction of two adjacent LED regions, the horizontal distance D3 and the vertical distance D3′ between two adjacent LEDs 1 in different LED regions are both smaller than the distance ISO of the LEDs 1 in the LED wafer 100. In one embodiment, D3 and D3′ are between 1 μm and 50 μm. In one embodiment, the LED wafer 100 to be transferred can be replaced by the LED carrier 100′.

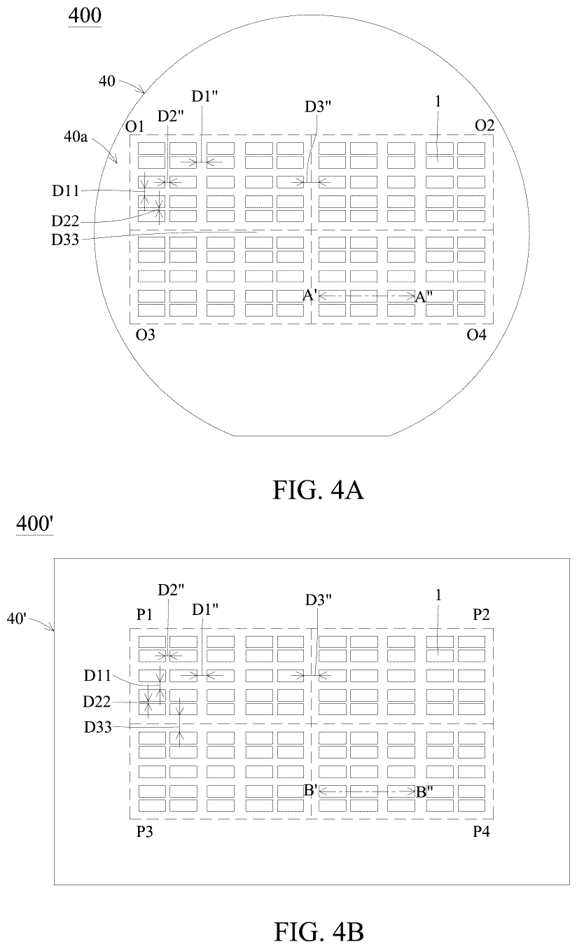

Referring to FIG. 4A. In one embodiment, the semiconductor device is a LED 1, and the LED wafer 400 includes a plurality of LEDs 1 formed on an upper surface 40a of the substrate 40. The LED wafer 400 includes a plurality of LED regions in virtual, such as LED regions O1-O4. N LEDs 1 are arranged in an array, such as a 5×5 array, and are located in one LED region. In one embodiment, the arrangement of the LEDs 1, the allocations of the regions, the area of each region and the quantity of the regions can be adjusted as needed.

The cross-sectional view of the LED wafer 400 along A′-A″ can be referred to FIG. 1B and the relevant paragraphs. Compared with the previous embodiment of FIG. 1A, in each of the LED regions O1-O4, the plurality of LEDs 1 has spacings gradually decreasing outward from the center of the region, and the arrangements of the LEDs in different regions are the same (spacing gradually decreases from the center toward the outside).

In one embodiment, 5×5 LEDs 1 are arranged in an array in the LED region O1 of the LED wafer 400, the plurality of LEDs 1 in the region O1 has spacings decreasing outward from the center of the LED region O1. The horizontal distance between the LED 1 located in the center of the LED region O1 and the adjacent LED 1 adjacent to the LED 1 located in the center of the LED region O1 is D1″, and the vertical distance between the LED 1 located in the center of the LED device region O1 and the adjacent LED 1 adjacent to the LED 1 located in the center of the LED region O1 is D11. The horizontal distance between the adjacent LED 1 and the more peripheral LED 1 is D2″, and the vertical distance between the adjacent LED 1 and the more peripheral LED 1 is D22. D1″>D2″, and D11>D22. The same result also can be obtained in the LED regions O2-O4. In the LED wafer 400, the distance between two adjacent LEDs located in one LED region is larger than the distance between two adjacent LEDs located in different LED regions. That is, D1″>D2″>D3″, and D11>D22>D33. In one embodiment, D3″ and D33 are between 1 μm and 50 μm.

As shown in FIG. 4B. In one embodiment, the semiconductor device is a LED 1, and the LED carrier 400′ includes a plurality of LEDs 1 formed on the carrier 40′. Similar to the LED carrier 100′, the LED carrier 400′ includes a plurality of LED regions in virtual, such as LED regions P1-P4. N LEDs 1 are arranged in an array, such as a 5×5 array, and are located in one LED region. In one embodiment, the arrangement of the LEDs 1, the allocations of the regions, the area of each region and the quantity of the regions can be adjusted as needed.

The cross-sectional view of the LED carrier 400′ along B′-B″ can be referred to FIG. 2B and the relevant paragraphs. Compared with the LED carrier 100′, the distance between two adjacent LEDs located in each of the LED regions P1-P4 gradually decreases outward from the center of the region, and the arrangements of the LEDs in different regions are the same (spacing gradually decreases from the center toward the outside).

In one embodiment, 5×5 LEDs 1 are arranged in an array in the LED region P1 of the LED carrier 400′. The distance between two adjacent LEDs gradually decreases outward from the center of the LED region P1. The horizontal distance between the LED 1 located in the center of the LED region P1 and the adjacent LED 1 adjacent to the LED 1 in the center of the LED region P1 is D1″, and the vertical distance between the LED 1 located in the center of the LED region P1 and the adjacent LED 1 adjacent to the LED 1 in the center of the LED region P1 is D11. The horizontal distance between the adjacent LED 1 and the more peripheral LED 1 is D2″, and the vertical distance between the adjacent LED 1 and the more peripheral LED 1 is D22. D1″>D2″, and D11>D22. The same result also can be obtained in the LED regions P2-P4. In the LED carrier 400′, the distance between two adjacent LEDs located in one LED region is larger than the distance between two adjacent LEDs located in different LED regions. That is, D1″>D2″>D3″, and D11>D22>D33. In one embodiment, D3″ and D33 are between 1 μm and 50 μm.

In one embodiment, similar to the structure as shown in FIG. 2A, the LED carrier with a constant distance between two adjacent LEDs 1 can be obtained by transferring the LEDs 1 from the LED wafer 400 or the LED carrier 400′ to another carrier with the regional laser transferring process.

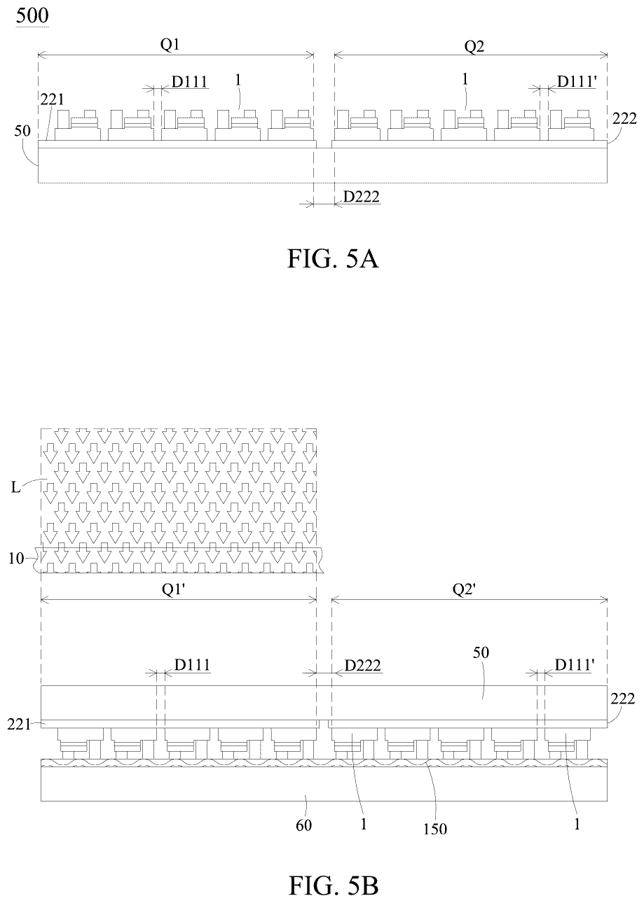

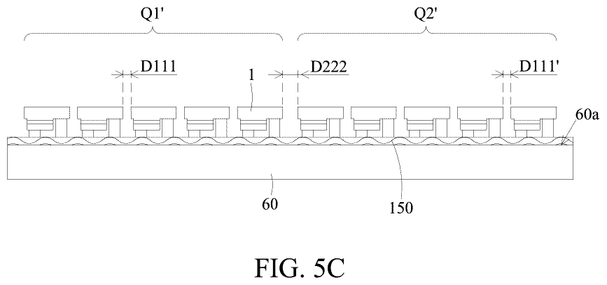

FIGS. 5A to 5C illustrate a regional transferring process of transferring multiple LEDs 1 on a LED carrier 500 to a temporary carrier 60. FIG. 5A shows a cross-sectional view of a LED carrier 500. Similar to the LED carrier 100′, the LED carrier 500 includes a carrier 50. A first adhesive sublayer 221 and a second adhesive sublayer 222 are located on the upper surface 50a′ of the carrier 50, and located in the LED regions Q1 and Q2. In the LED region Q1, a plurality of LEDs 1 is arranged on the first adhesive sublayer 221 at a constant distance D111. In the LED region Q2, a plurality of LEDs 1 is arranged on the second adhesive sublayer 222 at a constant distance D111′. The distance between two adjacent LEDs 1 on the bonduray between the LED regions Q1 and Q2 is D222.

Compared with the LED carrier 100′, the LED 1 in FIG. 5A is presented with a simplified structure (detailed are omitted), and is arranged on the carrier 50 with the electrodes facing outward. The first adhesive sublayer 221 and the second adhesive sublayer 222 in the LED regions Q1 and Q2 are separated from each other. In one embodiment, the first adhesive sublayer 221 and the second adhesive sublayer 222 have the same composition, and can be formed by selectively etching a continuous adhesive layer (not shown) on the upper surface 50a′. In one embodiment, when D111=D111′=D222, the distance between two adjacent LEDs located in one LED region is equal to the distance between two adjacent LEDs located in different LED regions. When D111=D111′>D222, the distance between two adjacent LEDs located in one LED region is larger than the distance between two adjacent LEDs located in different LED regions. When D111=D111′<D222, the distance between two adjacent LEDs located in one LED region is smaller than the distance between two adjacent LEDs located in different LED regions.

As shown in FIG. 5B, the LED carrier 500 is turned over and placed on the temporary carrier 60. In the LED region Q1 of the LED carrier 500, the first adhesive sublayer 221 is ablated and decomposed by the laser beam L, so that the plurality of LEDs 1 is separated from the carrier 50, and then placed on an adhesive layer 150 of the temporary carrier 60. Through the same region transferring process, a plurality of LEDs 1 in another LED region Q2 can be transferred to the adhesive layer 150 of the temporary carrier 60. In one embodiment, the carrier 50 with the LED region Q1 and the LED region Q2 can be separated as two independent sub-carriers (not shown).

Referring to FIG. 5C, a LED carrier 600 is formed after the carrier 50 is removed. In one embodiment, during the regional laser transferring process, one side of the LED 1 is connected to the carrier 50 (the first adhesive sublayer 221 and the second adhesive sublayer 222), and the other side of the LED 1 is connected to the carrier 60 (the adhesive layer 150). Therefore, the distance between two adjacent LEDs 1 after transfer is equal to the distance between two adjacent LEDs 1 on the LED carrier 500. The LED carrier 600 includes a carrier 60. An adhesive layer 150 is located on the upper surface 60a of the carrier 60, continuously located in the LED regions Q1′ and Q2′. In the LED region Q1′, a plurality of LEDs 1 is arranged on the adhesive layer 150 at a constant distance D111. In the LED region Q2′, a plurality of LEDs 1 is arranged on the adhesive layer 150 at a constant distance D111′. The distance between two adjacent LEDs 1 located at a junction of LED regions Q1 and Q2 is D222. In one embodiment, D111 is not equal to D111′.

According to embodiments of the present application, the regional laser transferring process can be performed by using LED wafers and/or LED carriers with different configurations and designs, and can be adjusted the LED carrier such as (1) the arrangement of multiple LEDs in one LED region; (2) the distance between two adjacent LEDs in one LED region; and (3) the distance between two adjacent LEDs in different LED regions.

Although some embodiments of the present disclosure and their advantages have been described in detail, various changes, substitutions and alterations may be made herein without departing from the spirit and scope of the disclosure as defined by the appended claims.

What is claimed is:

1. A semiconductor device arrangement, comprising:
a carrier, having an upper surface;
an adhesive layer, arranged on the upper surface;
a plurality of first semiconductor devices, arranged in a first region on the adhesive layer; and
a plurality of second semiconductor devices, arranged in a second region on the adhesive layer;
wherein the first region abuts the second region;
wherein, any two adjacent first semiconductor devices of the plurality of first semiconductor devices are separated by a first distance, any one of the plurality of first semiconductor devices and any one of the plurality of second semiconductor devices, which are adjacent to each other, are separated by a second distance, and the first distance is larger than the second distance.

2. The semiconductor device arrangement according to claim 1, wherein the plurality of first semiconductor devices has spacings increasing outward from a center of the first region.

3. The semiconductor device arrangement according to claim 1, wherein the plurality of first semiconductor devices has spacings decreasing outward from a center of the first region.

4. The semiconductor device arrangement according to claim 1, wherein the plurality of first semiconductor devices arranged in the first region and the plurality of second semiconductor devices arranged in the second region have a same arrangement.

5. The semiconductor device arrangement according to claim 1, wherein the adhesive layer is a continuous layer.

6. The semiconductor device arrangement according to claim 1, wherein the adhesive layer comprises a first adhesive sublayer and a second adhesive sublayer which are separated from each other, the first region is located on the first adhesive sublayer, and the second region is located on the second adhesive sublayer.

7. The semiconductor device arrangement according to claim 6, wherein the first adhesive sublayer and the second adhesive sublayer have a same composition.

8. The semiconductor device arrangement according to claim 1, wherein any two adjacent second semiconductor devices of the plurality of second semiconductor devices are separated by a distance identical to the first distance.

9. The semiconductor device arrangement according to claim 1, wherein the carrier includes a glass substrate, a sapphire substrate, or a quartz substrate.

10. The semiconductor device arrangement according to claim 1, wherein the second distance is between 1 μm and 50 μm.

11. The semiconductor device arrangement according to claim 1, wherein the plurality of first semiconductor devices comprises a first semiconductor device with an electrode facing away from the carrier.

12. The semiconductor device arrangement according to claim 1, wherein the plurality of first semiconductor devices comprises a first semiconductor device with an electrode facing the carrier.

13. The semiconductor device arrangement according to claim 1, wherein the carrier is penetrable by a laser beam.

14. The semiconductor device arrangement according to claim 13, wherein the adhesive layer is decomposable upon an irradiation of the laser beam.

15. The semiconductor device arrangement according to claim 13, wherein a gas is generated when the adhesive layer is irradiated by the laser beam.

16. The semiconductor device arrangement according to claim 1, wherein the plurality of first semiconductor devices and the plurality of second semiconductor devices have an identical quantity.
